(19) United States
(12) Patent Application Publication
(10) Pub. No.: US 2014/0055961 A1
(43) Pub. Date: Feb. 27, 2014

(54) Printed Circuit Boards with Recesses

(71) Applicants: Shayan Malek, San Jose, CA (US); Nicholas G. L. Merz, San Francisco, CA (US); Michael B. Wittenberg, Sunnyvale, CA (US)

(72) Inventors: Shayan Malek, San Jose, CA (US); Nicholas G. L. Merz, San Francisco, CA (US); Michael B. Wittenberg, Sunnyvale, CA (US)

(21) Appl. No.: 13/593,352

(22) Filed: Aug. 23, 2012

(51) Int. Cl. H05K 3/34; H05K 3/46; H05K 7/00

(52) U.S. Cl. 361/748; 29/840; 29/846

(57) ABSTRACT

Printed circuit boards are provided with recess-mounted components. The components may be mounted within recesses in the surface of a printed circuit board substrate that are larger than the component. A solder stencil may be used to mount the components in a recess. The solder stencil may have curved portions between a planar portion and a depressed portion. The difference in the lateral width of the recess and the lateral width of the component may be configured to allow the planar portion and the depressed portion to be placed against the surface of the printed circuit board without damaging edges of the recess during solder application processes. The recess may be formed by placing a dummy component having a size and shape that is larger than the size and shape of the recess-mounted component against a portion of the printed circuit board during board formation operations.

### BACKGROUND

This relates to assemblies of electrical and mechanical components for electronic devices, and, more particularly, printed circuit board structures having electronic components mounted in recesses in the printed circuit board structures.

Electronic devices use integrated circuits and other electrical components. These components are typically mounted to the surface of a printed circuit board using solder. Solder is typically applied to the printed circuit board using a solder stencil.

Printed circuit boards may be formed from substrates such as fiberglass-filled epoxy. In complex designs, multiple board layers may be laminated to form a multilayer printed circuit board.

In a typical printed circuit board arrangement, electronic components are attached to a substantially planar surface of the outermost board layer. Vias may be formed to interconnect board layers. Some arrangements have been proposed in which components are fully or partially embedded in the printed circuit board structures.

However, it can be difficult to accurately apply solder to a printed circuit board for mounting embedded components.

It would therefore be desirable to be able to provide improved printed circuit board structures for electronic devices.

### SUMMARY

Electronic devices may be provided that include electronic components. These electronic components may include integrated circuits, printed circuit boards, and electrical devices that are mounted to printed circuit boards.

Printed circuit board substrates may be formed from one or more layers of dielectric material. In multilayer substrates multiple printed circuit board layers may be laminated together. Conductive layers may be patterned to form interconnects. Interconnects may also be formed by drilling vias. Vias may be drilled mechanically or using laser drilling.

Embedded components may be mounted within recesses in the surface of a printed circuit board substrate. The recesses may include portions of the printed circuit board that are formed from fewer printed circuit board layers than other portions of the printed circuit board. The recesses in the printed circuit board may have a lateral size along a surface of the printed circuit board that is larger than the lateral size of the electronic component that is mounted in the recess. The difference in size between the recess and the associated mounted component may be determined in relation to a known bend radius of a solder placement structure to be used in mounting the component in the recess.

The outer surface of the printed circuit board in the recess may include a patterned metal layer configured to receive solder for mounting electronic components in the recess. The solder may be applied by aligning a solder placement structure such as a solder stencil having curved portions with associated bend radii over the printed circuit board. If desired, the solder stencil may include openings over the recess and/or openings over non-recessed portions of the printed circuit board. The curved portions of the solder stencil may allow the solder stencil to be concurrently placed in contact with the printed circuit board in the recess and in non-recessed portions.

Recesses in a multi-layered printed circuit board may be formed by attaching a substrate such as a dummy component to the printed circuit board while forming the layers of the multi-layered printed circuit board. The dummy component may have a size that is larger than the size of an electronic component to be mounted in the recess. Placing the dummy component against the printed circuit board during formation of the printed circuit board may prevent additional board layers from being formed in the location of the dummy component.

Further features of the invention, its nature and various advantages will be more apparent from the accompanying drawings and the following detailed description of the preferred embodiments.

### BRIEF DESCRIPTION OF THE DRAWINGS

FIG. 1 is a perspective view of an illustrative electronic device with a printed circuit board having recess-mounted electronic components in accordance with an embodiment of the present invention.

FIG. 2 is a cross-sectional side view of an illustrative electronic device having a printed circuit board showing how the printed circuit board may be provided with recesses and electronic components mounted in the recesses in accordance with an embodiment of the present invention.

FIG. 3 is a partially exploded perspective view of an illustrative printed circuit board showing how layers of the printed circuit board may be provided with recesses having patterned conductive contacts to accommodate embedded components in accordance with an embodiment of the present invention.

FIG. 4 is a perspective view of an illustrative printed circuit board of the type shown in FIG. 3 in which multiple integrated circuits have been mounted in recesses having a lateral size that is larger than the lateral size of the electronic component in accordance with an embodiment of the present invention.

FIG. 5 is a cross-sectional side view of an illustrative two-sided printed circuit in accordance with an embodiment of the present invention.

FIG. 6 is a cross-sectional side view of the printed circuit of FIG. 5 following the formation of holes and following attachment of a backing layer in accordance with an embodiment of the present invention.

FIG. 7 is a cross-sectional side view of the printed circuit of FIG. 6 following attachment of a printed circuit prepreg layer in accordance with an embodiment of the present invention.

FIG. 8 is a cross-sectional side view of the printed circuit of FIG. 7 following the formation of holes in the prepreg layer in accordance with an embodiment of the present invention.

FIG. 9 is a cross-sectional side view of the printed circuit of FIG. 8 following the formation an additional conductive layer in accordance with an embodiment of the present invention.

FIG. 10 is a cross-sectional side view of the printed circuit of FIG. 9 following the formation openings in the conductive layer in accordance with an embodiment of the present invention.

FIGS. 11A-11B show cross-sectional side views of a multi-layer printed circuit formed from structures of the type shown in FIG. 10 showing how a dummy component may be used to form a recess in the multi-layer printed circuit in accordance with an embodiment of the present invention.

FIGS. 12A-12B are diagrams showing how a solder stencil with curved portions may be used to mount electronic components in a recess in a printed circuit board in accordance with an embodiment of the present invention.

FIGS. 13A-13C are diagrams showing how a solder stencil with curved portions may be used to mount electronic components in a recess in a printed circuit board in a two-stage solder application process in accordance with an embodiment of the present invention.

FIG. 14 is a flow chart of illustrative steps involved in attaching components in recesses in printed circuit boards using solder in accordance with an embodiment of the present invention.

FIG. 15 is a flow chart of illustrative steps involved in attaching components in recesses in printed circuit boards using a multi-step solder application process in accordance with an embodiment of the present invention.

FIG. 16 is a flow chart of illustrative steps involved in forming a multi-layer printed circuit board with recesses using a dummy component structure in accordance with an embodiment of the present invention.

FIG. 17 is a perspective view of an illustrative solder patterning tool having depressed portion and a planar portion in accordance with an embodiment of the present invention.

### DETAILED DESCRIPTION

Electronic devices can be provided with electronic components such as optical parts, camera mounting structures, integrated circuits, printed circuits, flexible printed circuits, rigid printed circuits such as printed circuit boards, buttons, vibrators, and electrical structures. Printed circuit boards may be provided with recesses having patterned metal layers for mounting additional electronic components such as integrated circuits to the printed circuit board.

Electronic devices that may be provided with printed circuit boards having electronic components mounted in recesses in the printed circuit boards include desktop computers, computer monitors, computer monitors containing embedded computers, wireless computer cards, wireless adapters, televisions, set-top boxes, gaming consoles, routers, portable electronic devices such as laptop computers, tablet computers, and handheld devices such as cellular telephones and media players, and small devices such as wrist-watch devices, pendant devices, headphone and earpiece devices, and other wearable and miniature devices. Portable devices such as cellular telephones, media players, tablet computers and other handheld electronic devices are sometimes described herein as an example.

Electronic components that may be mounted in a recess in a printed circuit board may include integrated circuits, switches, wires, connectors, microphones, speakers, light-emitting diodes and other components that can serve as displays and status indicators, or other suitable structures and electrical components. Configurations in which components such as integrated circuits are mounted in recesses in printed circuit boards are sometimes described herein as an example. This is merely illustrative. Any suitable components may be mounted in a recess in a printed circuit boards if desired.

When used in electronic devices, an electronic component that is mounted in a recess in a printed circuit board may help save space, may help allow board dimensions to be adjusted to satisfy design constraints (e.g., to increase board thickness without unnecessarily increasing the overall height of a printed circuit board assembly, to decrease board thickness, etc.), may improve structural strength, etc.

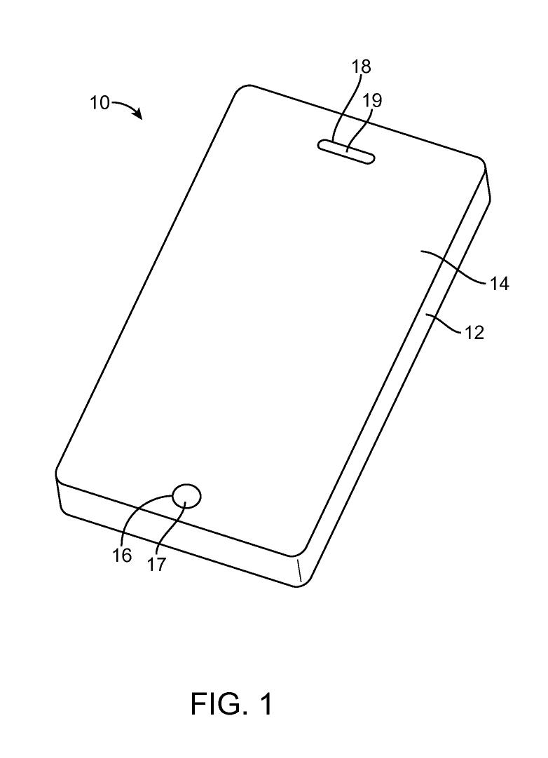

An illustrative electronic device of the type that may be provided with a printed circuit board having recesses is shown in FIG. 1. Electronic device 10 may be a portable electronic device or other suitable electronic device. For example, electronic device 10 may be a laptop computer, a tablet computer, a somewhat smaller device such as a wrist-watch device, pendant device, or other wearable or miniature device, a cellular telephone, a media player, etc.

Device 10 may include a housing such as housing 12. Housing 12, which may sometimes be referred to as a case, may be formed of plastic, glass, ceramics, fiber composites, metal (e.g., stainless steel, aluminum, etc.), other suitable materials, or a combination of these materials. In some situations, parts of housing 12 may be formed from dielectric or other low-conductivity material. In other situations, housing 12 or at least some of the structures that make up housing 12 may be formed from metal elements.

Device 10 may have a display such as display 14. Display 14 may include a touch sensor layer such as a layer on which a pattern of indium tin oxide (ITO) electrodes or other suitable transparent electrodes have been deposited to form a capacitive touch sensor array and a layer that contains an array of display pixels. In addition to these functional display layers, display 14 may include one or more structural layers such as a flexible or rigid cover layer and/or may be mounted on a support structure (e.g., a rigid support).

Device 10 may, if desired, have user interface components such as buttons 17 or speaker component 19 that occupy openings such as openings 16 and 18 respectively in an optional rigid cover layer of flexible display 14.

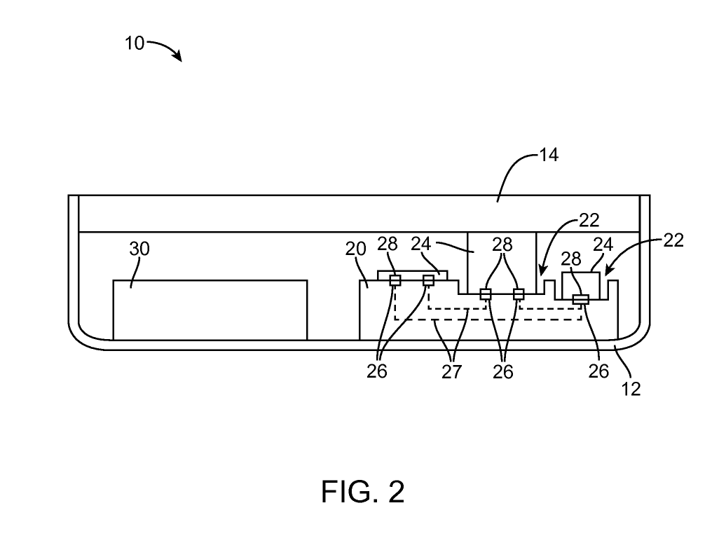

As shown in FIG. 2, device 10 may include internal structures such as internal electronic components. Internal electronic components in device 10 may include circuitry such as printed circuit board 20, battery 30, and electronic components 24. Electronic components 24 may, for example, be integrated circuits or other components that are electrically coupled to conductive interconnects 27 in printed circuit board 20. Conductive interconnects 27 may be coupled to electrical contacts 26 on an outer surface of printed circuit board 20. Electrical contacts 28 of components 24 may be attached to contacts 26 on printed circuit board 20 (e.g., using solder).

Printed circuit board 20 may include one or more layers of dielectric and one or more layers of conductor. Typical printed circuit boards may have core layers that are formed from dielectrics. Examples of suitable materials that may be used in forming a printed circuit board include dielectrics such as fiberglass-filled epoxy (e.g., in a rigid printed circuit board) and polyimide (e.g., in a flexible printed circuit board of the type sometimes referred to as a flex circuit). For example, printed circuit boards may be formed from FR-2 (phenolic cotton paper), FR-3 (cotton paper and epoxy), FR-4 (woven glass and epoxy), FR-5 (woven glass and epoxy), FR-6 (matte glass and polyester), G-10 (woven glass and epoxy), CEM-1 (cotton paper and epoxy), CEM-2 (cotton paper and epoxy), CEM-3 (woven glass and epoxy), CEM-4 (woven glass and epoxy), CEM-5 (woven glass and polyester), paper impregnated with phonolic resin, polystyrene, polyimide, polytetrafluoroethylene (PTFE), plastic, other polymers, ceramics, or other suitable dielectrics.

In multilayer printed circuit boards, core layers may be attached to each other using attachment layers such as layers of prepreg (i.e., pre-impregnated layers of fiber and resin). Layers of copper or other conductive materials may be formed on the surfaces of the printed circuit board core layers and prepreg layers. For example, a core layer may have upper and lower surfaces that are covered with a layer of metal such as copper. Conductive lines 27 may be formed from this type of metal layer that has been patterned to form conductive traces on the printed circuit board.

As shown in FIG. 2, printed circuit board 20 may include one or more recesses 22. Portions of conductive layers such as copper layers may be exposed to form conductive contacts 26 of printed circuit board 20. Contacts 26 may be formed within recesses 22 of printed circuit board 20 and on non-recessed portions of printed circuit board 20. Components such as components 24 may be mounted to printed circuit board 20 within recesses 22 and/or on non-recessed portions of printed circuit board 20.

Recesses 22 may be formed from portions of a multi-layer printed circuit board that have fewer layers than non-recessed portions of the printed circuit board. Printed circuit board 20 may have one or more recesses 22 that have a common depth or having different depths.

The depth of each recess may be determined by the number of printed circuit board layers in the recessed region of the printed circuit board and the number of printed circuit board layers in adjacent non-recessed portions of the printed circuit board.

For example, printed circuit board 10 may include ten printed circuit board layers in a non-recessed portion of the printed circuit board and six printed circuit board layers in a recessed portion. However, this is merely illustrative. If desired, a printed circuit board such as printed circuit board 20 may include less than 8 layers, more than 8 layers, 8 to 10 layers, 7 to 10 layers, 7 to 12 layers, more than 9 layers, or more than 10 layers in a non-recessed portion and less than 6 layers, more than 6 layers, 4 to 8 layers, 4 to 6 layers, 5 to 8 layers, 5 to 9 layers or more than 9 layers, in a recessed portion.

Recessed portions 22 of printed circuit board 20 may be formed by removing layers such as conductive layers, dielectric layers, prepreg layers, etc. from the printed circuit board, or may be formed using a dummy component that prevents some layers of printed circuit board 20 from being formed in the recessed regions of the printed circuit board during manufacturing of the printed circuit board.

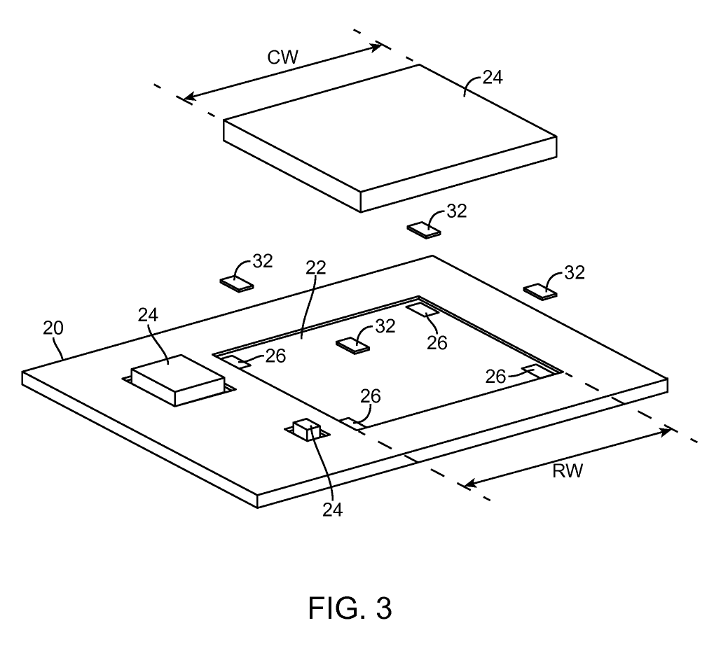

A partially exploded perspective view of an illustrative printed circuit board having recesses for mounting electronic components is shown in FIG. 3. As shown in FIG. 3, printed circuit board 20 may include conductive contacts 26 in a recess 22. Electronic components such as components 24 may be electrically coupled to contacts 26 using solder pads 32. Solder pads 32 may be formed over contacts 26 using tools such as a solder stencil and a solder squeegee.

Each component 24 may be a microprocessor, a microcontroller, an audio chip, an application-specific integrated circuit, or other integrated circuit. If desired, components 24 may be discrete electrical components (e.g., resistors, inductors, capacitors, and transistors).

As shown in FIG. 3, a given recess 22 may have an associated lateral width RW. Width RW of a recess 22 may be larger than the width CW of an associated component to be mounted in that recess. Providing printed circuit board 20 with a recess 22 having a width RW that is larger than the lateral width CW of a component to be mounted in the recess may facilitate the application of solder in forming solder pads 32 using a solder stencil.

In order to apply solder to contacts 26 in recess 22, a solder stencil having curved portions that allow the stencil to lay flat against printed circuit board 20 in recessed portions and non-recessed portions may be used. Width RW of recess 22 may be designed to accommodate a solder stencil having curved portions. The curved portions of a solder stencil may have an associated minimum bend radius. Width RW of recess 22 may be designed to limit the bend radius required to lay the solder stencil flat against the surface of printed circuit board 20.

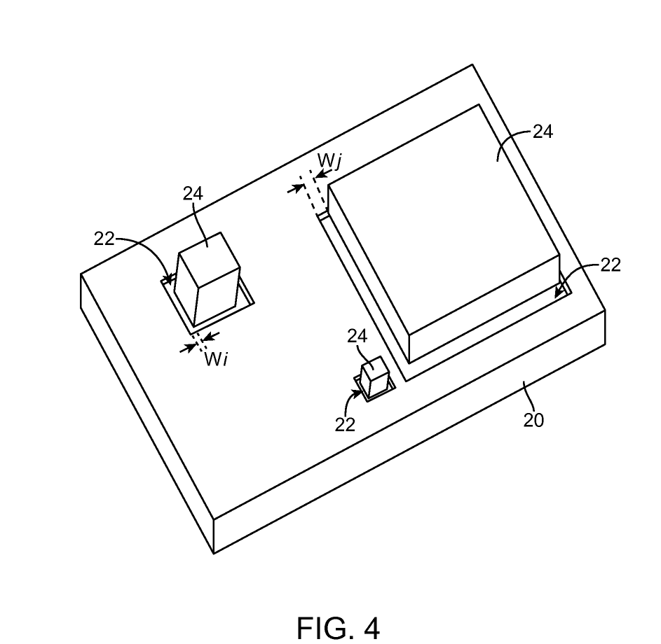

As shown in FIG. 4, following assembly of printed circuit board 20 and components 24 (i.e., following attachment of components 24 to board 20), each recess 22 may include a portion between the mounted component 24 and an adjacent non-recessed portion that has a width (e.g., widths Wi and Wj) that is based on the bend radius of the solder stencil used to mount that component 24.

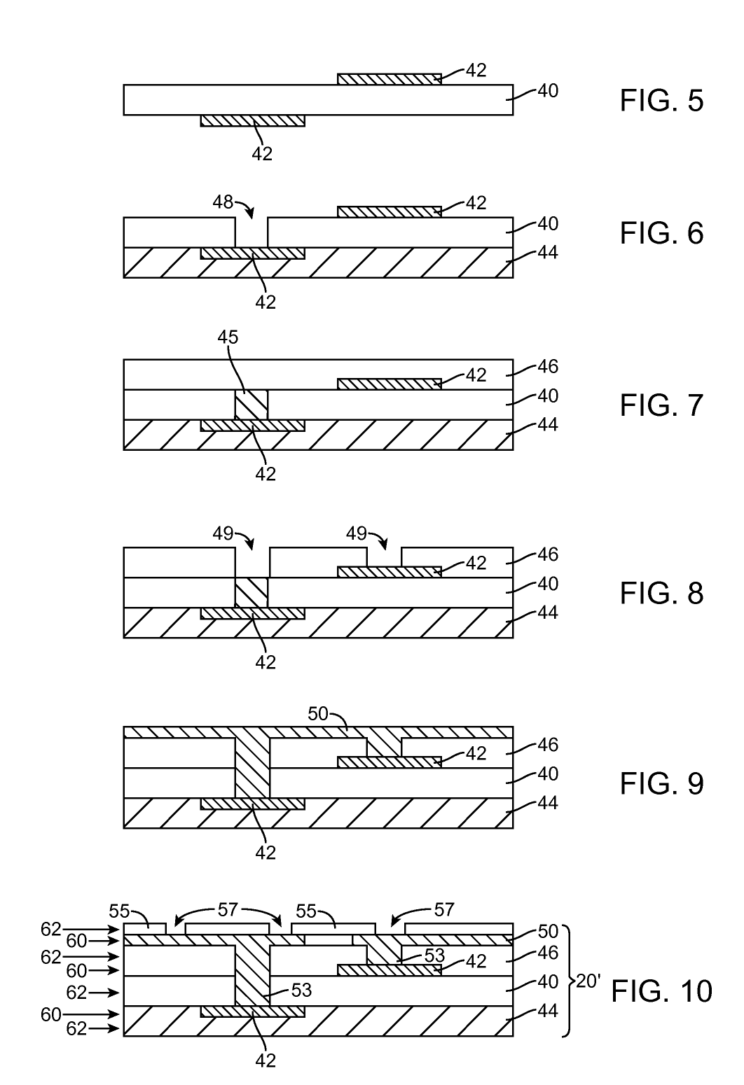

An illustrative arrangement for forming a portion of printed circuit board 20 from multiple layers of printed circuit material is shown in FIGS. 5, 6, 7, 8, 9, and 10. This approach is merely illustrative. In general, any suitable fabrication process may be used in forming printed circuit board 20, if desired.

As shown in FIG. 5, patterned conductive traces such as traces 42 may be formed on the upper and lower surfaces of a layer of printed circuit board material such as layer 40. Layer 40 may be, for example, a cured layer of fiberglass-filled epoxy. Conductive traces 42 may be formed from a metal such as copper (as an example). Photolithography or other patterning techniques may be used in forming patterned traces 42.

Following formation of printed circuit layer 40 of FIG. 5, openings may be formed in layer 40, as shown by illustrative opening 48 in FIG. 6. Openings such as opening 48 may be formed by laser processing, machining (e.g., drilling or other machining techniques using a cutting tool such as a drill bit or milling machine cutter), etching, etc.

As shown in FIG. 6, an additional layer such as layer 44 may be formed on layer 40 over portions of conductive traces 42. Layer 44 may, as an example, be a temporary support structure to be used in supporting printed circuit board 20 before upper and lower layers of printed circuit material are added. Layer 44 may be formed from a flexible polymer sheet with a layer of removable adhesive (as an example). However, this is merely illustrative. If desired, layer 44 may be a permanent layer such as a dielectric layer or other layer of a printed circuit board. If desired, additional printed circuit board layers may be attached to layer 44 (e.g., additional conductive layers, additional dielectric layers, solder mask layers, etc.). In the example of FIGS. 6, 7, 8, 9, and 10, layer 44 forms a bottom external layer of a printed circuit board.

An upper layer of prepreg such as layer 46 of FIG. 7 (i.e., fiberglass-filled epoxy or other printed circuit board material that has been cured sufficiently to become tacky but that is not completely rigid) may be added to the upper surface of printed circuit layer 40.

Conductive materials such as conductive material 45 may be incorporated into vias in layer 40 prior to attachment of layer 46 (e.g., using via metal layer formation techniques such as electrochemical deposition). Following formation of via metallization 45 and prepreg layer 46 (e.g., using a lamination tool or other lamination equipment), layer 46 may be cured (e.g., by applying heat using the lamination tool).

As shown in FIG. 8, additional openings such as openings 49 may be formed in layer 46. Forming openings 49 in layer 46 may expose portions of conductive traces 42 and/or via metallization 45. Openings such as opening 49 may be formed by laser processing, machining (e.g., drilling or other machining techniques using a cutting tool such as a drill bit or milling machine cutter), etching, etc.

As shown in FIG. 9, following formation of openings 49 in layer 46, metal layers such as metal layer 50 may be formed. Metal layer 50 may be, for example, a layer of copper foil that has not been patterned. Metal layer 50 may include portions that fill openings 49 or additional conductive material may be used to fill openings 49 prior to forming layer 50.

As shown in FIG. 10, layer 50 may be patterned (e.g., using photolithography, laser direct imaging, or other patterning techniques) and an additional dielectric layer 55 having openings may be formed over layer 50. Layer 50 may be used to form conductive contacts in a recess in a printed circuit board such as printed circuit board 20 of FIG. 2.

A partially formed printed circuit board such as board 20′ may include one or more conductive layers 60 and one or more dielectric layers 62. Each conductive layer 60 may be formed from a patterned metal layer such as a patterned copper layer. Each dielectric layer 62 may be formed from fiberglass-filled epoxy or other printed circuit board material (e.g., FR-2, FR-3, FR-4, etc.). Vias such as vias 53 may electrically couple conductive layers 60 to other conductive layers 60 through one or more dielectric layers 62.

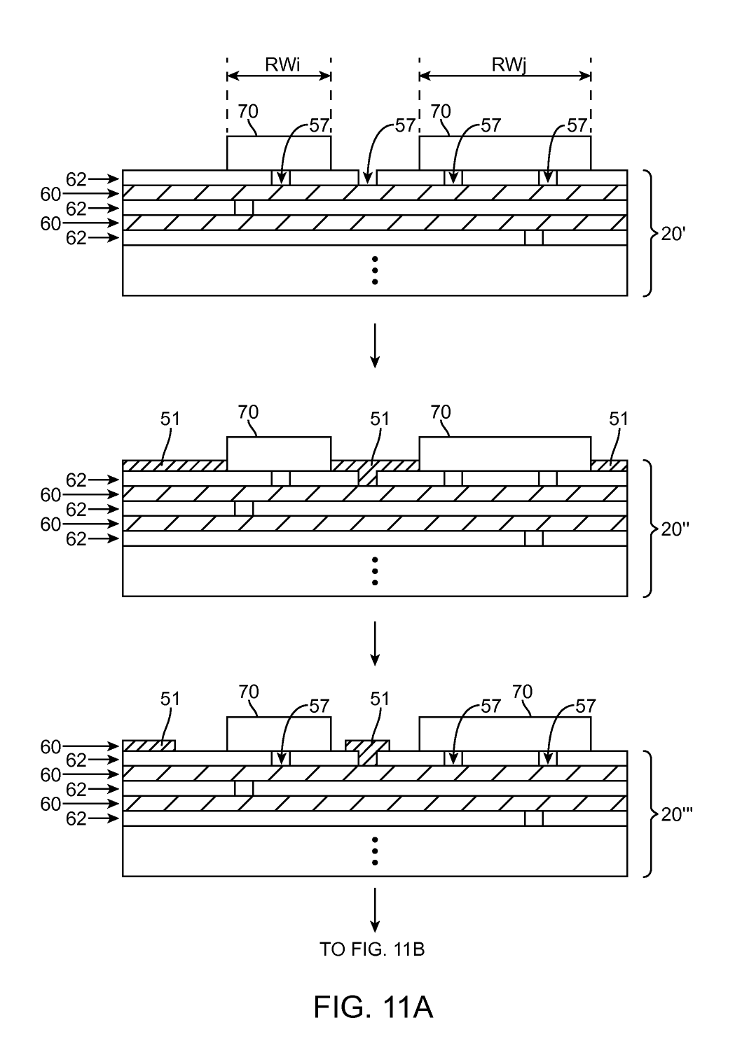

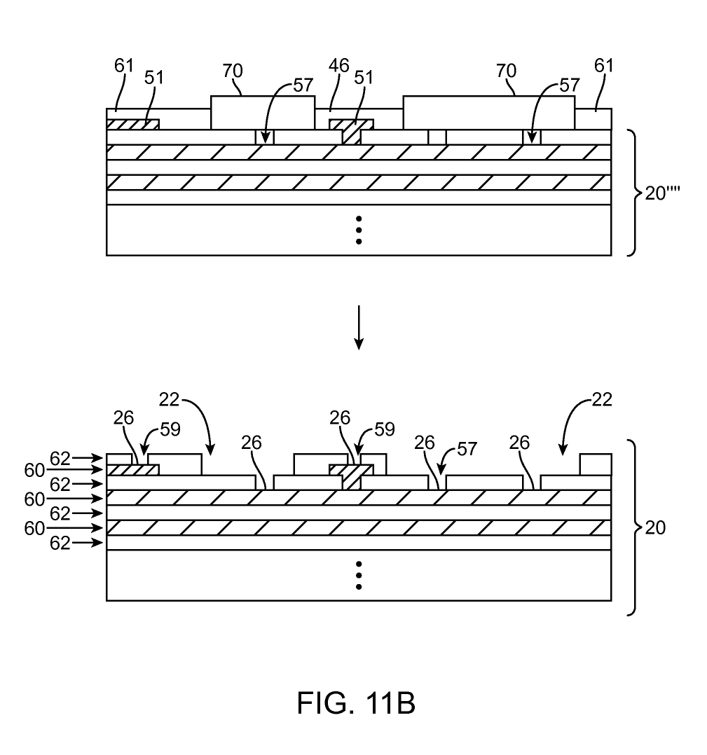

Partially formed printed circuit board 20′ of FIG. 10 may be using to form a printed circuit board having recesses as shown in the illustrative arrangement for forming a recessed printed circuit of FIGS. 11A and 11B.

As shown in FIG. 11A, placeholder substrates such as dummy components 70 may be attached to a partially formed printed circuit board such as board 20′ having multiple conductive layers 60 (e.g., patterned conductive layers) and dielectric layers 62. Dummy components 70 may be formed from plastic, rubber or other suitable material. Dummy components 70 may have a lateral width (e.g., widths RWi and RWj) equal to the desired lateral width of a recess in a finished printed circuit board. For example, width RWi and RWj may be larger than the lateral width of electronic components to be mounted in the associated recesses.

After attaching dummy components 70, metal layers such as metal layer 51 may be formed on partially formed printed circuit board 20′ to form partially formed printed circuit board 20″. Metal layer 51 may be, for example, a layer of copper foil that has not been patterned. Metal layer 51 may include portions that fill some of openings 57 or additional conductive material may be used to fill openings 57 prior to forming layer 51. As shown in FIG. 11A, dummy components 70 may prevent layer 51 from being formed over some portions of board 20″.

After forming metal layer 51, metal layer 51 may be patterned (e.g., using photolithography, laser direct imaging, or other patterning techniques) to form partially formed printed circuit board 20′″.

As shown in FIG. 11B, an additional dielectric layer 55 may be formed over layer 51 to form partially formed printed circuit board 20″″. Openings such as openings 59 may then be formed in layer 55 and dummy components 70 may be removed.

As shown in FIG. 11B, after removal of dummy components 70, recesses 22 may remain in regions of printed circuit board 20 in which additional printed circuit board layers such as layers 51 and 61 have been prevented from forming by dummy components 70. Openings 59 in layer 61 may be used to expose portions of layer 51 for forming conductive contacts 26 in non-recessed portions of a printed circuit board such as printed circuit board 20 of FIG. 2. Openings such as openings 57 may be used to expose portions of a deeper conductive layer of printed circuit board 20 to form conductive contacts 26 in recesses 22 of board 20. However, the arrangement of FIGS. 11A and 11B is merely illustrative. If desired, one, two, three, or more than three additional conductive layers 60 and one, two, three, or more than three additional dielectric layers 62 may be formed on partially formed printed circuit board 20′ while dummy components 70 are attached to the partially formed board 20′ to form recessed portions in a finished printed circuit board. If desired, one or more layer (e.g., conductive layers and/or dielectric layers) may be removed from a multi-layer printed circuit board to form recesses such as recesses 22 in the printed circuit board.

Electronic components such as components 24 of FIGS. 2, and 3 may be attached to printed circuit board 20 having recesses 22 using solder pads such as solder pads 32 (FIG. 3).

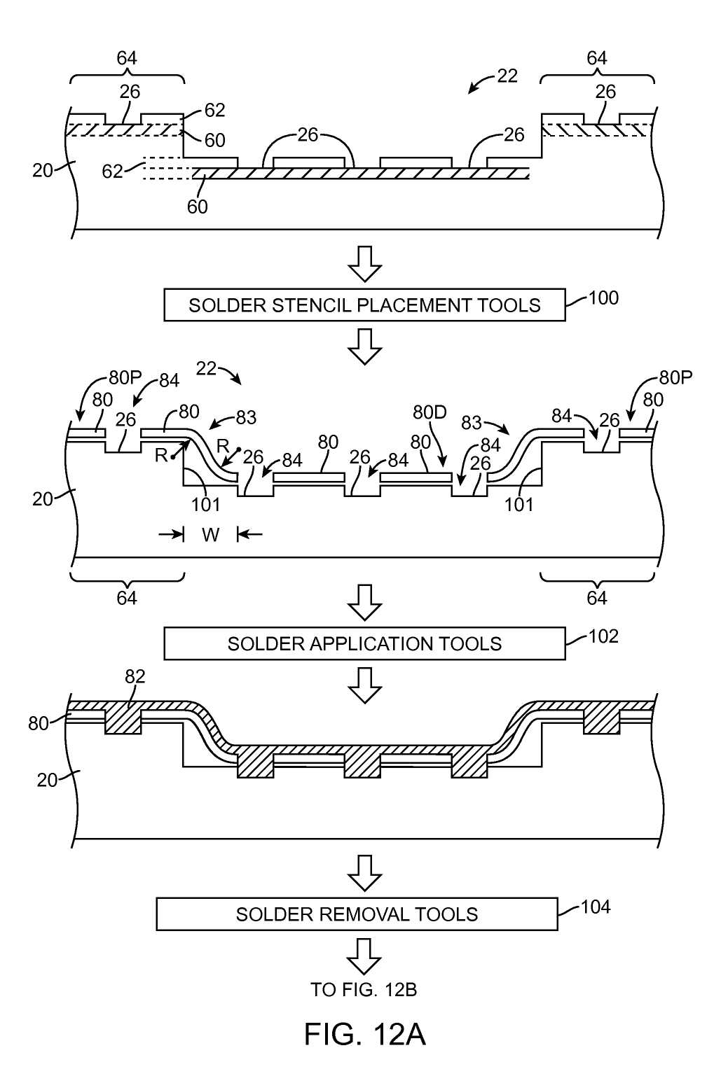

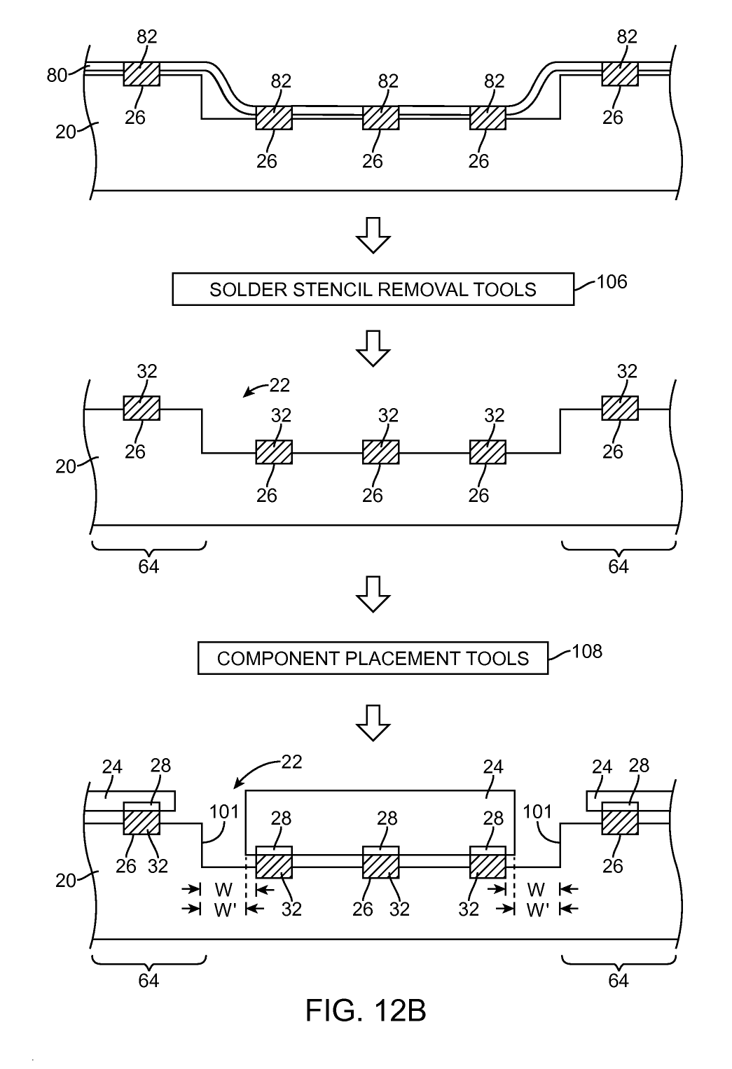

FIGS. 12A and 12B form a diagram showing how components may be mounted to a printed circuit board having recesses using solder. Initially, a printed circuit board such as board 20 that has exposed conductive contacts 26 in recess 22 and in non-recessed portions 64 may be provided.

Solder stencil placement tools 100 (e.g., mechanical or manual placement tools for holding, aligning and securing a solder stencil over a printed circuit board) may be used to align solder stencil 80 over printed circuit board 20. Solder stencil placement tools 100 may align openings 84 in stencil 80 over conductive contacts 26 in recess 22 and in non-recessed portions 64 of board 20.

As shown in FIG. 12A, solder stencil 80 may include curved portions 83 that allow depressed portion 80D of stencil 80 to lay flat against board 20 in recess 22 and planar portion 80P to lay against board 20 in non-recessed portions 64. Curved portions 83 may have a bend radius R. Conductive contacts 26 in recess 22 may be formed sufficiently far (i.e., at a minimum distance W) from sidewalls 101 of recess 22 so that bend radius R of curved portions 83 of stencil 80 is within a suitable range (e.g., a range that does not result in damage to stencil 80 or board 20 during alignment of stencil 80). As examples, distance W may be between 500 and 700 microns, between 400 and 800 microns, between 400 and 500 microns, between 100 and 500 microns, greater than 100 microns, greater than 300 microns, or greater than 50 microns.

Following alignment of openings 84 of stencil 80 with contacts 26, solder application tools 102 (e.g., a solder dispenser) may be used to apply a layer of solder paste 82 over stencil 80 and into openings 84.

Solder removal tools 104 (e.g., a solder squeegee or other suitable tool) may be used to remove solder paste 82 from the exterior surface of stencil 80 leaving solder paste 82 in openings 84 and in contact with conductive contacts 26 of board 20.

Solder stencil removal tools 106 (e.g., mechanical, automated, or manual stencil removal tools) may be used to remove stencil 80 from printed circuit board 20, thereby forming solder pads 32 in contact with conductive contacts 26 of printed circuit board 20.

Component placement tools 108 (e.g., robotic or manual electronic component placement tools) may be used to mount components such as components 24 to printed circuit board 20. As shown in FIG. 12B, components 24 may be mounted within a recess 22 or on non-recessed portions 64 of board 20. Conductive contacts 28 on components 24 may be placed in contact with solder pads 32. Solder pads 32 may then be reflowed under components 24, thereby securing components 24 to printed circuit board 20. As shown in FIG. 12B, following attachment of components 24, recess 22 may include a portion between component 24 and sidewalls 101 of recess 22 having a width W′. Width W′ may have a value of between 500 and 700 microns, between 300 and 700 microns, between 500 and 1000 microns, between 500 and 1500 microns, between 200 and 300 microns, or greater than 100 microns, as examples. Width W′ may be substantially equal to width W or may be different from width W.

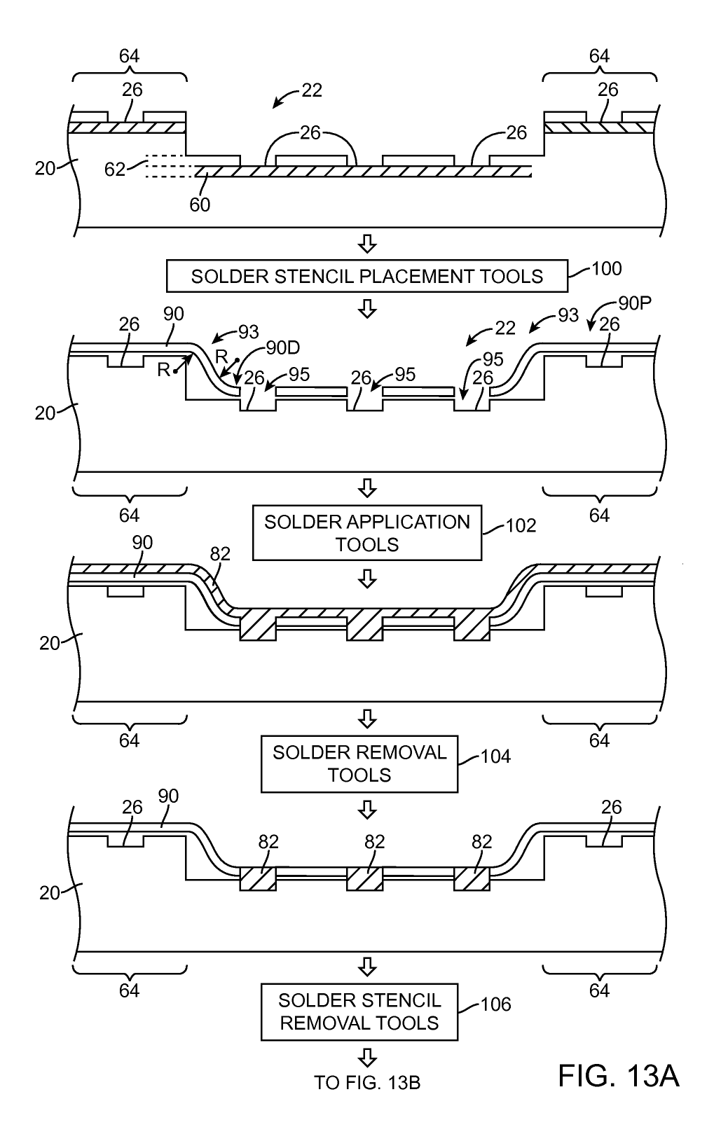

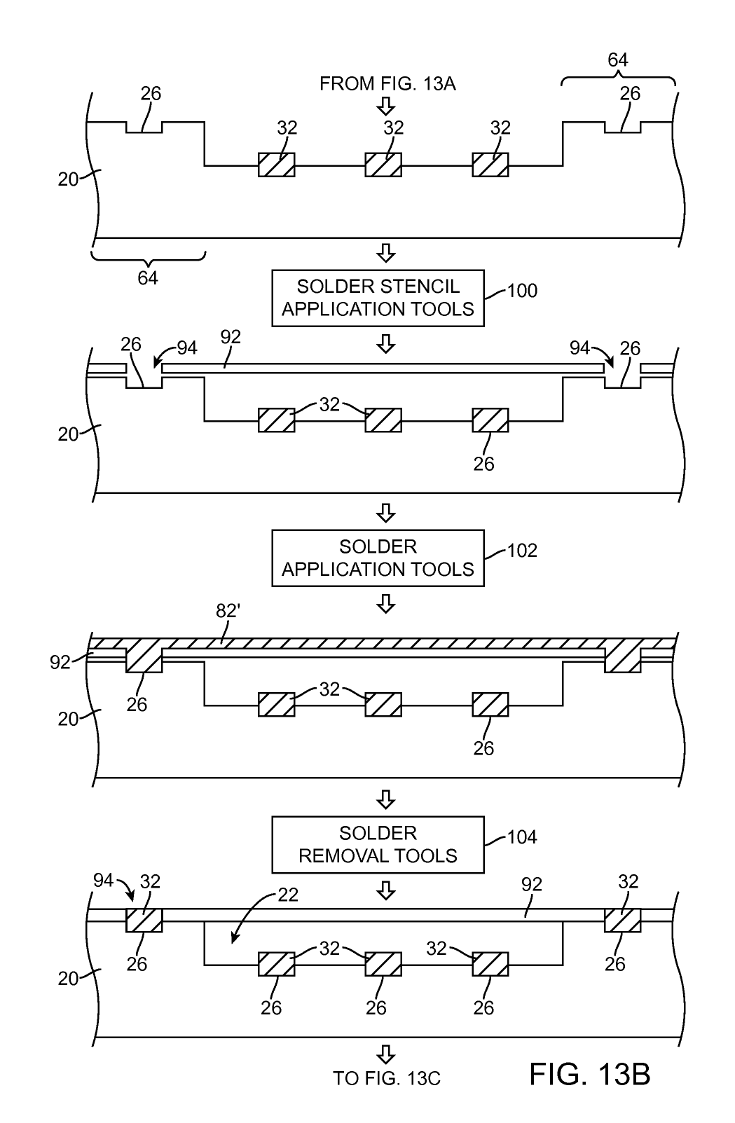

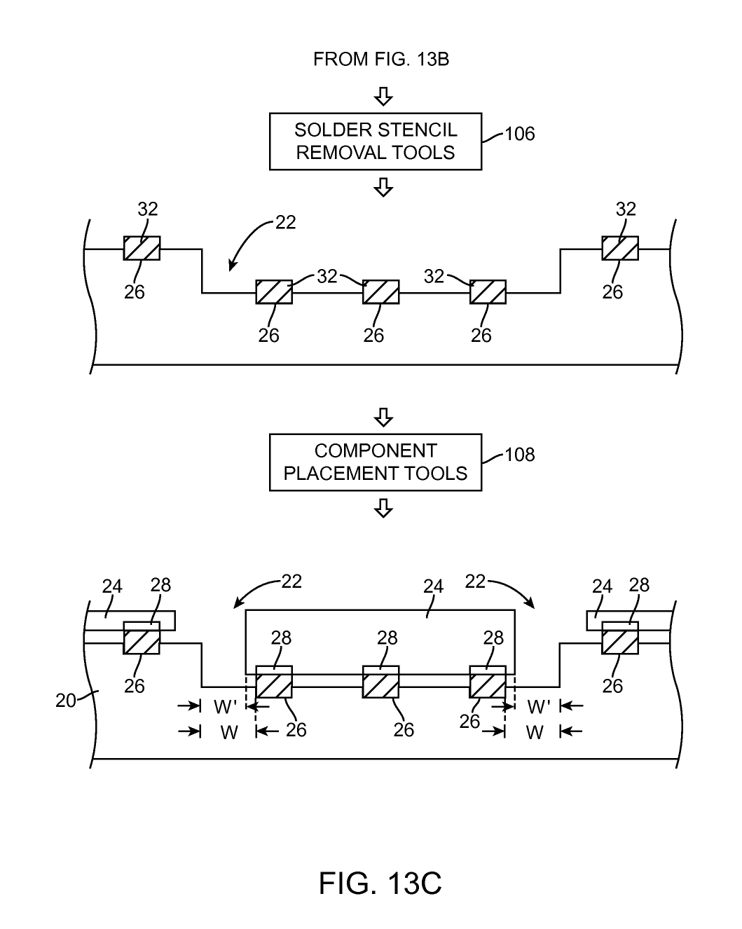

FIGS. 13A, 13B, and 13C form a diagram showing how components may be mounted to a printed circuit board having recesses with a two-step (two-stage) solder application process. As in the example of FIGS. 12A and 12B, initially, a printed circuit board such as board 20 that has exposed conductive contacts 26 in recess 22 and in non-recessed portions 64 may be provided.

Solder stencil placement tools 100 (e.g., mechanical or manual placement tools for holding, aligning and securing a solder stencil over a printed circuit board) may be used to align solder stencil 90 over printed circuit board 20. Solder stencil placement tools 100 may align openings 95 in stencil 90 over conductive contacts 26 in recess 22. Solder stencil 90 may be aligned so that portions of stencil 90 that are free of openings are placed over non-recessed portions 64 while openings 95 of stencil 90 are aligned over contacts 26 in recess 22.

As shown in FIG. 13A, solder stencil 90 may include curved portions 93 that allow depressed portion 90D of stencil 90 to lay flat against board 20 in recess 22 and planar portion 90P to lay against board 20 in non-recessed portions 64. Curved portions 93 may have a bend radius R. Conductive contacts 26 in recess 22 may be formed sufficiently far (i.e., at a minimum distance W) from sidewalls 101 of recess 22 so that bend radius R of curved portions 93 of stencil 90 is within a suitable range (e.g., a range that does not result in damage to stencil 90 or board 20 during alignment of stencil 90).

Following alignment of openings 95 of stencil 90 with contacts 26, solder application tools 102 (e.g., a solder dispenser) may be used to apply a layer of solder paste 82 over stencil 90 and into openings 95.

Solder removal tools 104 (e.g., a solder squeegee or other suitable tool) may be used to remove solder paste 82 from the exterior surface of stencil 90 leaving solder paste 82 in openings 95 and in contact with conductive contacts 26 of board 20.

Solder stencil removal tools 106 (e.g., mechanical, automated, or manual stencil removal tools) may be used to remove stencil 90 from printed circuit board 20, thereby forming solder pads 32 (see FIG. 13B) in contact with conductive contacts 26 of printed circuit board 20.

Solder stencil placement tools 100 may then be used to align an additional solder stencil 92 over printed circuit board 20. Solder stencil placement tools 100 may align openings 94 in stencil 92 over conductive contacts 26 in non-recessed portions 64 of printed circuit board 20. Solder stencil 92 may be a substantially planar solder stencil that covers recesses such as recess 22 in printed circuit board 20 when stencil 92 is aligned with contacts 26 in non-recessed portions 64.

Following alignment of openings 94 of stencil 92 with contacts 26 in non-recessed portions 64, solder application tools 102 (e.g., a solder dispenser) may be used to apply an additional layer of solder paste such as solder paste 82′ over stencil 92 and into openings 94.

Solder removal tools 104 may be used to remove solder paste 82′ from the exterior surface of stencil 92 leaving solder paste 82′ in openings 94 and in contact with conductive contacts 26 of board 20.

As shown in FIG. 13C, solder stencil removal tools 106 may be used to remove stencil 92 from printed circuit board 20, thereby forming solder pads 32 (see FIG. 13B) in contact with conductive contacts 26 of printed circuit board 20.

Component placement tools 108 (e.g., robotic or manual electronic component placement tools) may be used to mount components such as components 24 to printed circuit board 20 that has had solder pads formed using a two-step solder application process. As shown in FIG. 13C, components 24 may be mounted within a recess 22 or on non-recessed portions 64 of board 20. Conductive contacts 28 on components 24 may be placed in contact with solder pads 32. Solder pads 32 may then be reflowed under components 24, thereby securing components 24 to printed circuit board 20. As shown in FIG. 13C, following attachment of components 24, recess 22 may include a portion between component 24 and sidewalls 101 of recess 22 having a width W′. Width W′ may have a value of between 500 and 700 microns, between 300 and 700 microns, between 500 and 1000 microns, between 500 and 1500 microns, between 200 and 300 microns, or greater than 100 microns, as examples. Width W′ may be substantially equal to width W or may be different from width W.

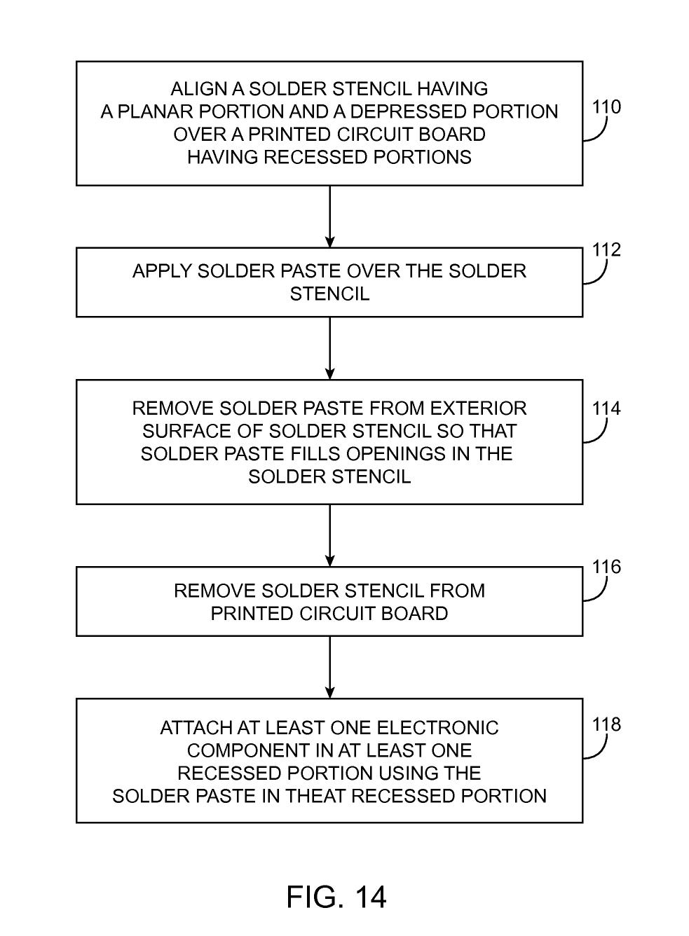

Illustrative steps involved mounting electronic components to a printed circuit board having recesses are shown in FIG. 14.

At step 110, a solder patterning tool such as a solder stencil having a planar portion and a depressed portion and openings in the planar portion and the depressed portion may be aligned over a printed circuit board having recessed portions (see, e.g., solder stencil 80 of FIGS. 12A and 12B). The depressed portion may be placed against a recessed surface in a recessed portion of the printed circuit board and the planar portion may be placed against the surface of the printed circuit board in a non-recessed portion of the printed circuit board.

At step 112, solder material such as solder paste may be applied over the solder patterning tool.

At step 114, the solder paste may be removed from the exterior surface of the solder stencil so that solder paste fills the openings in the solder stencil. Removing the solder paste from the exterior surface of the solder stencil may include wiping the exterior surface of the solder stencil with a solder squeegee (e.g., using manual or mechanical means).

At step 116, the solder stencil may be removed from the printed circuit board. Solder pads formed from the solder paste that filled the openings in the solder stencil may remain on contact pads on the printed circuit board after removal of the solder stencil (see, e.g., FIG. 12B).

At step 118, an electronic component such as component 24 of FIG. 12B may be attached to the printed circuit board in at least one of the recessed portions using the solder paste that has been applied in that recessed portion. Additional electronic components may be attached to solder paste that has been applied in non-recessed portions.

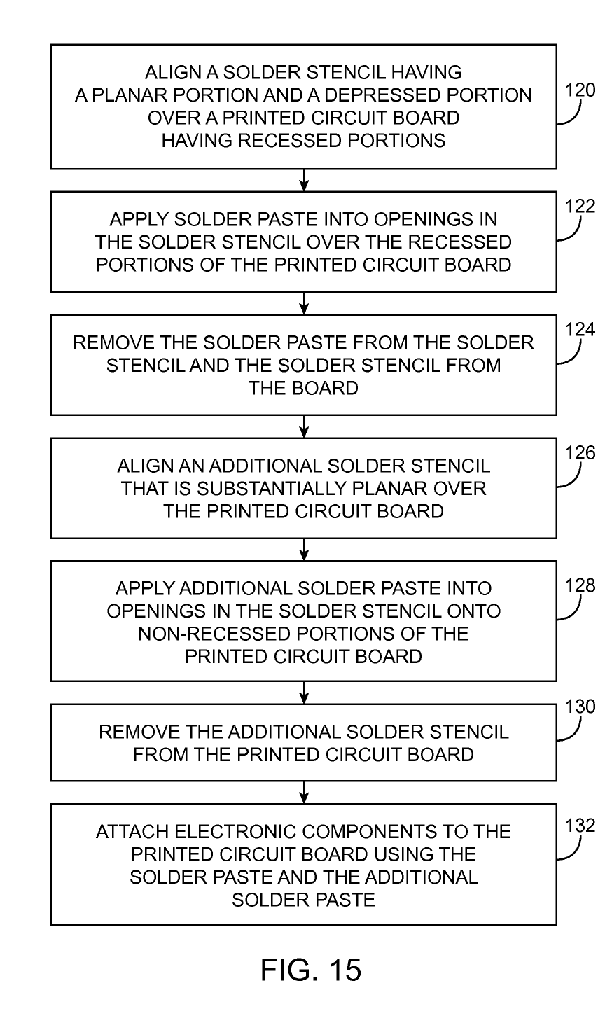

Illustrative steps involved mounting electronic components to a printed circuit board having recesses using a two-stage solder application process are shown in FIG. 15.

At step 120, a solder patterning tool such as a solder stencil having a planar portion and a depressed portion and openings in the depressed portion may be aligned over a printed circuit board having recessed portions (see, e.g., solder stencil 90 of FIG. 13A). The depressed portion may be placed against a recessed surface in a recessed portion of the printed circuit board and the planar portion may be placed against the surface of the printed circuit board in a non-recessed portion of the printed circuit board.

At step 122, solder material such as solder paste may be applied over at least the depressed portions of solder patterning tool.

At step 124, the solder paste may be removed from the exterior surface of the solder stencil so that solder paste fills the openings in the depressed portion of the solder stencil. Removing the solder paste from the exterior surface of the solder stencil may include wiping the exterior surface of the solder stencil with a solder squeegee (e.g., using manual or mechanical means). At step 124, the solder stencil may be removed from the printed circuit board. Solder pads formed from the solder paste that filled the openings in the depressed portion of the solder stencil may remain on contact pads in the recess after removal of the solder stencil (see, e.g., FIG. 13B).

At step 126, an additional solder patterning tool such as a planar solder stencil with openings and without any depressed portions may be aligned over the printed circuit board having recessed portions (see, e.g., solder stencil 92 of FIG. 13B). A portion of the planar solder stencil may cover the solder paste that remains on the contact pads in the recess.

At step 128, additional solder material such as solder paste may be applied over the additional solder patterning tool and into openings in the additional solder patterning tool over the non-recessed portions of the printed circuit board.

At step 130, the solder stencil may be removed from the printed circuit board. The solder paste on the exterior surface of the additional solder stencil may be removed (e.g., using a solder squeegee) prior to removing the additional solder stencil (see, e.g., FIGS. 13B and 13C).

At step 132, an electronic component such as component 24 of FIG. 13C may be attached to the printed circuit board in at least one of the recessed portions using the solder paste that has been applied in that recessed portion. Additional electronic components may be attached to solder paste that has been applied in non-recessed portions.

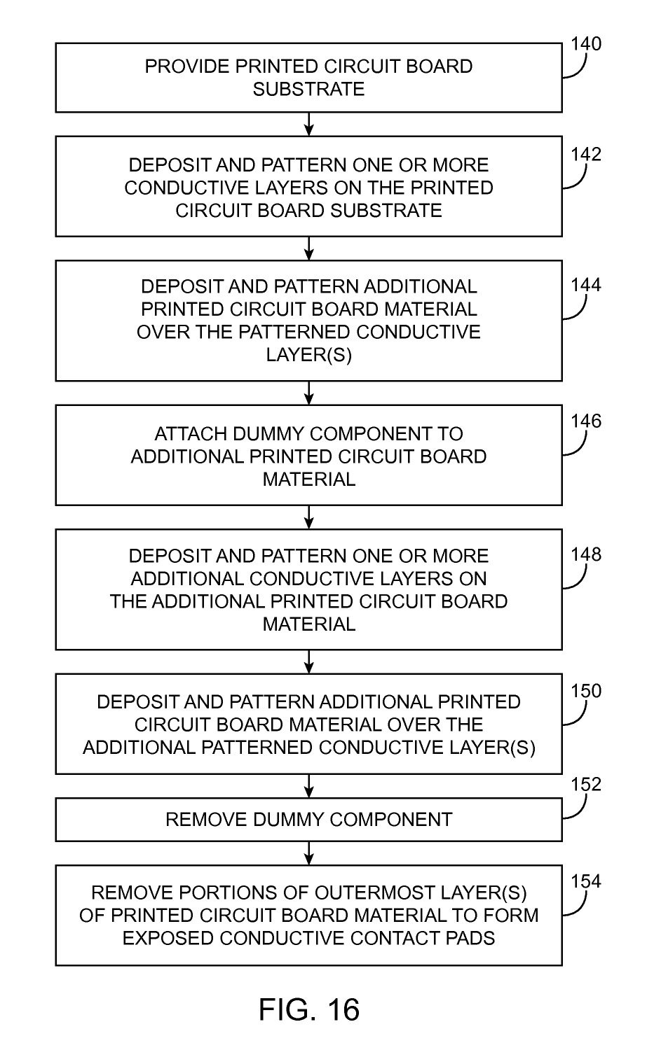

Illustrative steps involved forming a printed circuit board with recesses using a dummy component are shown in FIG. 16.

At step 140, a printed circuit substrate such as substrate 40 of FIG. 5 may be provided.

At step 142, one or more patterned conductive layers may be formed on the printed circuit board substrate (e.g., by depositing and patterning a one or more conductive layers as described above in connection with, for example, FIG. 5).

At step 144, additional printed circuit board material may be deposited and patterned over the patterned conductive layers as described above in connection with FIGS. 6, 7, and 8, as examples.

At step 146, a substrate having the size and shape of a dummy component may be attached to the additional printed circuit board material (see, e.g., FIG. 11A). The size of the dummy component may be larger than the size of an electronic component to be mounted in the recess in order to allow application of solder in the recess using a solder patterning tool such as a solder stencil.

At step 148, one or more additional conductive layers may be deposited and patterned on the additional printed circuit board material.

At step 150, further additional printed circuit board material may be deposited and patterned (see, e.g., layer 61 of FIG. 11B) over the one or more additional conductive layers.

At step 152, the dummy component substrate may be removed.

At step 154, portions of the outermost printed circuit board layer or layers may be removed to form exposed conductive contact pads. Some of the exposed conductive contact pads may be formed in the location at which the dummy component was attached to form conductive contact pads in the recess. The outermost printed circuit board layer or layers may be removed using etching, or other suitable patterning processes.

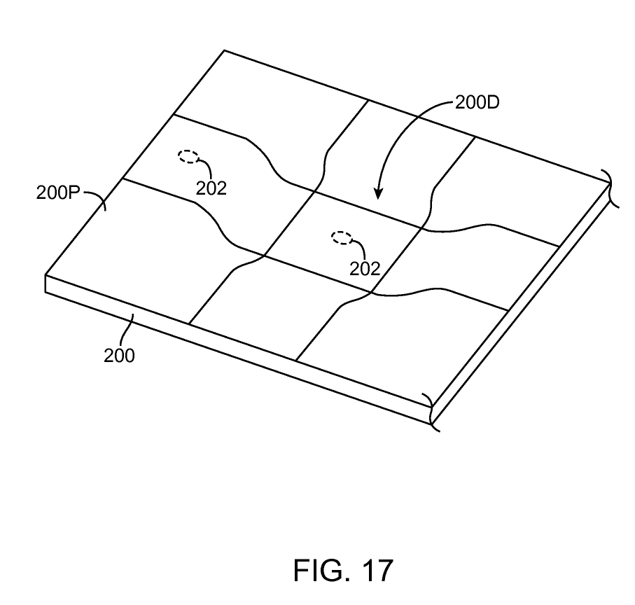

FIG. 17 is a perspective view of a solder stencil that may be used in performing component attachment operations for forming a printed circuit board with recesses-mounted components.

As shown in FIG. 17, a solder placement tool such as solder patterning tool 200 may include a lower planar portion such as depressed portion 200D that is substantially surrounded by an upper planar portion such as planar portion 200P. Planar portion 200P may have a planar surface that is parallel to a planar portion of depressed portion 200D. Openings 202 through which solder material such as solder paste may be applied to a printed circuit board may be provided in depressed portion 200D and/or planar portion 200P. Solder stencils 80, 90 and 92 of FIGS. 12A, 12B, and 13A may be embodiments of a solder placement tool such as solder patterning tool 200.

The foregoing is merely illustrative of the principles of this invention and various modifications can be made by those skilled in the art without departing from the scope and spirit of the invention.

What is claimed is:

1. A method of attaching electronic components to a printed circuit board with solder that is placed on the printed circuit board using a solder placement tool having an upper planar portion and a lower planar portion each with openings, wherein the printed circuit board has a surface, a recess in the surface, and conductive contacts on a recessed surface in the recess, the method comprising:
aligning the openings in the lower planar portion of the solder placement tool with the conductive contacts on the recessed surface in the recess;
providing solder on the conductive contacts on the recessed surface through the openings in the lower planar portion of the solder placement tool; and
attaching at least one of the electronic components to the printed circuit board using the solder that has been provided on the conductive contacts.

2. The method defined in claim 1 wherein the printed circuit board also includes additional conductive contacts on a non-recessed portion of the surface, the method further comprising:
while aligning the openings in the lower planar portion of the solder placement tool with the conductive contacts on the recessed surface in the recess, aligning the openings in the upper planar portion of the solder placement tool with the additional conductive contacts on the non-recessed portion.

3. The method defined in claim 2, further comprising:
providing additional solder on the additional conductive contacts on the non-recessed portion of the surface through the openings in upper planar portion of the solder placement tool.

4. The method defined in claim 3, further comprising:
attaching an additional one of the electronic components to the printed circuit board using the additional solder that has been provided on the additional conductive contacts.

5. The method defined in claim 2 wherein the solder that has been provided on the conductive contacts comprises solder paste and wherein attaching the at least one of the electronic components to the printed circuit board using the solder that has been provided on the conductive contacts further comprises:
placing conductive contact pads attached to the at least one of the electronic components in contact with the solder paste; and
reflowing the solder paste that has been provided on the conductive contacts.

6. The method defined in claim 2 wherein aligning the openings in the lower planar portion of the solder placement tool with the conductive contacts on the recessed surface in the recess comprises:
placing the lower planar portion of the solder stencil against the recessed surface in the recess.

7. The method defined in claim 6, further comprising:
while placing the lower planar portion of the solder stencil against the recessed surface in the recess, placing the upper planar portion of the solder stencil against the non-recessed portion of the surface.

8. A method of attaching electronic components to a printed circuit board having a recess in a surface and conductive contacts on a recessed surface in the recess using a first solder patterning tool having a planar portion, a depressed portion, and openings in the depressed portion and a second solder patterning tool having openings, the method comprising:
placing the first solder patterning tool on the printed circuit board with the depressed portion of the first solder patterning tool against the recessed surface;
providing solder paste into the openings in the depressed portion;
removing the first solder patterning tool from the printed circuit board;
placing the second solder patterning tool on the printed circuit board; and
providing solder paste into the openings in the second solder patterning tool.

9. The method defined in claim 8 wherein the printed circuit board includes a non-recessed portion on the surface, the method further comprising:
while placing the first solder patterning tool on the printed circuit board with the depressed portion of the first solder patterning tool against the recessed surface, placing the planar portion of the first solder patterning tool against the non-recessed portion on the surface.

10. The method defined in claim 9 wherein placing the second solder patterning tool on the printed circuit board comprises:
aligning the openings in the second solder patterning tool with conductive contacts on the non-recessed portion on the surface.

11. The method defined in claim 10 wherein the second solder patterning tool includes a portion that is free of openings and wherein placing the second solder patterning tool on the printed circuit board further comprises:
aligning the portion that is free of openings over the solder paste that has been provided into the openings in the depressed portion of the first solder patterning tool.

12. The method defined in claim 8, further comprising:
attaching an electronic component to the printed circuit board using the solder paste that has been provided into the openings in the first solder patterning tool.

13. The method defined in claim 12, further comprising:
attaching an additional electronic component to the printed circuit board using the solder paste that has been provided into the openings in the second solder patterning tool.

14. A method of forming a multi-layer printed circuit board with a recess, comprising:
forming a plurality of printed circuit board layers;
placing a substrate having a size against the plurality of printed circuit board layers in a location, wherein the size of the substrate is larger than a size of an electronic component to be mounted in the recess;
forming at least one additional printed circuit board layer on the plurality of printed circuit board layers; and
removing the substrate.

15. The method defined in claim 14 wherein forming the plurality of printed circuit board layers comprises:
providing a printed circuit board substrate;
depositing and patterning a plurality of conductive layers on the printed circuit board substrate; and
depositing and patterning additional printed circuit board material over the plurality of patterned conductive layers.

16. The method defined in claim 15 wherein forming the at least one additional printed circuit board layer on the plurality of printed circuit board layers comprises:
depositing and patterning at least one additional conductive layer on the plurality of printed circuit board layers.

17. The method defined in claim 16 wherein forming the at least one additional printed circuit board layer on the plurality of printed circuit board layers comprises:
depositing additional printed circuit board material over the at least one additional conductive layer.

18. The method defined in claim 15 wherein the printed circuit board substrate comprises woven glass, the method further comprising:
after removing the substrate, exposing at least one portion of a conductive layer in the plurality of printed circuit board layers in the location.

19. An electronic device, comprising:
a printed circuit board having a first portion and a second portion, wherein the first portion includes a first number of printed circuit board layers and wherein the second portion comprises a second number of printed circuit board layers that is less than the first number of printed circuit board layers; and
an electronic component mounted to the second portion, wherein the electronic component has a lateral width and wherein the second portion of the printed circuit board has a lateral width that is larger than the lateral width of the electronic component.

20. The electronic device defined in claim 19, wherein the second number of printed circuit board layers is at least three fewer than the first number of printed circuit board layers.

21. The printed circuit board defined in claim 20 wherein the first number of printed circuit board layers is at least eight and wherein the second number of printed circuit board layers is less than five.

22. The printed circuit board defined in claim 19 wherein the lateral width of the second portion of the printed circuit board is at least 500 microns larger than the lateral width of the electronic component.
